(19) United States
(12) Patent Application Publication
(10) Pub. No.: US 2025/0239307 A1
(43) Pub. Date: Jul. 24, 2025

(54) PARTIAL-FINE PROGRAM SCHEME FOR RELIABILITY RISK WORD LINES

(71) Applicant: Micron Technology, Inc., Boise, ID (US)

(72) Inventors: Yu-Chung LIEN, San Jose, CA (US); Hanping CHEN, Sunnyvale, CA (US); Yueh-Hung CHEN, Sunnyvale, CA (US); Zhenming ZHOU, San Jose, CA (US)

(21) Appl. No.: 18/985,910

(22) Filed: Dec. 18, 2024

Related U.S. Application Data
(60) Provisional application No. 63/623,984, filed on Jan. 23, 2024.

(51) Int. Cl. G11C 16/10; G06F 3/06; G11C 16/04; G11C 16/34

(52) U.S. Cl. CPC G11C 16/10; G06F 3/0619; G06F 3/0653; G06F 3/0659; G06F 3/0679; G11C 16/0483; G11C 16/349

(57) ABSTRACT

In some implementations, a memory device may receive a program command. The memory device may determine whether a portion of the memory is associated with a reliability risk. The memory device may determine, based on whether the portion of the memory is associated with the reliability risk, a selected program scheme to be used to program the host data to the portion of the memory, wherein the selected program scheme is one of a single-fine program scheme or a partial-fine program scheme, wherein the single-fine program scheme includes performing a fine pulse for each level of cells being programmed, of multiple levels of cells being programmed, and wherein the partial-fine program scheme includes performing multiple fine pulses for only a subset of the multiple levels of cells being programmed. The memory device may execute the program command by performing the selected program scheme.

### CROSS-REFERENCE TO RELATED APPLICATION

This patent application claims priority to U.S. Provisional Patent Application No. 63/623,984, filed on Jan. 23, 2024, entitled “PARTIAL-FINE PROGRAM SCHEME FOR RELIABILITY RISK WORD LINES,” and assigned to the assignee hereof. The disclosure of the prior application is considered part of and is incorporated by reference into this patent application.

### TECHNICAL FIELD

The present disclosure generally relates to memory devices, memory device operations, and, for example, to using a partial-fine program scheme for reliability risk word lines.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), phase-change memory (PCM), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source.

### BRIEF DESCRIPTION OF THE DRAWINGS

FIG. 1 is a diagram illustrating an example system capable of performing a partial-fine program scheme for reliability risk word lines.

FIG. 2 is a diagram of example components included in a memory device.

FIGS. 3A-3B are diagrams of examples associated with multi-fine program schemes for reliability risk word lines.

FIGS. 4A-4G are diagrams of examples associated with a partial-fine program scheme for reliability risk word lines.

FIG. 5 is a flowchart of an example method associated with a partial-fine program scheme for reliability risk word lines.

### DETAILED DESCRIPTION

Memory cells may undergo program erase cycles (PECs) in which host data is written to the memory cells, such as in response to receiving a program command from a host device, and in which the host data is later erased from the memory cells, such as in response to receiving an erase command from the host device. During some program schemes, a memory device may program a memory cell using two voltage pulses, including a first pulse (sometimes referred to as a coarse pulse and/or a coarse voltage), which may be used to set a voltage level of a memory cell in a general proximity of a final program voltage, and a second pulse (sometimes referred to as a fine pulse and/or a fine voltage), which may be used to set the voltage level of the memory cell to the final program voltage. Because in such program schemes only one fine pulse may be used to program the memory cell, the program scheme is sometimes referred to as a single-fine program scheme. Using a single-fine program scheme may result in data loss in certain portions of the memory (e.g., portions of the memory associated with a limited read write bandwidth (RWB)) because the single fine pulse may not accurately raise the memory cell voltage to a desired final program voltage.

In some examples, in order to improve a reliability of a memory, a double-fine program scheme may be implemented by the memory device, which may result in more precisely programmed cells and thus improved reliability, particularly for memory cells associated with a limited RWB. More particularly, during a double-fine program scheme, a memory device may use three pulses to program a memory cell, including a coarse pulse, a first fine pulse, which may be used to set the voltage level of the memory cell near to the final program voltage, and a second fine pulse, which may be used to fine tune the voltage level of the memory cell to the final program voltage. Using a double-fine program scheme may result in improved data retention for memory cells associated with a limited RWB, as compared to a single-fine program scheme, because using two fine pulses may more accurately raise the memory cell voltage to a desired final program voltage.

Although a double-fine program scheme may result in improved data retention as compared to a single-fine program scheme, the improvements come at a cost of higher power consumption and increased time needed to complete the double-fine program scheme. More particularly, the double-fine program scheme may take more time to complete than the single-fine program scheme because two fine pulses are used rather than the single fine pulse in the single-fine program scheme. Moreover, in light of the two fine pulses used, the double-fine program scheme may result in higher energy per bit (EPB) consumption than the single-fine program scheme. Accordingly, selection of a program scheme at a memory device may result in a tradeoff between relatively poor data retention, yet relatively low EPB consumption and relatively quick program procedures, on one hand when employing a single-fine program scheme, or else improved data retention, yet relatively high EPB consumption and relatively slow program operations, on the other hand when employing the double-fine program scheme.

In some implementations, a memory device may implement a single-fine program scheme for certain word lines (e.g., word lines that do not pose a reliability risk), and may implement a double-fine program scheme for other word lines (e.g., word lines that do pose a reliability risk). This may enable the memory device to reduce a programming time and/or an EPB consumption as compared to operations in which a double-fine program scheme is applied to all cells being programmed, while improving reliability as compared to operations in which a single-file program scheme is applied to all cells being programmed. However, applying a double-fine program scheme to certain word lines may result in an unnecessary programming time and/or power consumption penalty, because certain cells associated with a reliability risk word line may pose a relatively small reliability risk. For example, for certain multi-level cells, such as quad-level cells (QLCs) in which a cell is capable of being programmed to one of sixteen voltage levels corresponding to one of sixteen data states, cells being programmed to certain levels may pose a relatively low reliability risk while cells being programmed to certain other levels may pose a relatively high reliability risk. Implementation of a double-fine program scheme on all levels of cells being programmed may thus result in unnecessary power consumption and/or programming time penalty.

Some implementations described herein enable a program scheme that results in improved data retention as compared to using the single-fine program scheme for programming portions of a memory, while also resulting in reduced power consumption and quicker program procedures as compared to using a double-fine program scheme for programming portions of the memory. More particularly, in some implementations, a memory device may selectively implement a single-fine program scheme for portions of a memory that are not associated with a reliability risk, while implementing a partial-fine program scheme (e.g., a program scheme that uses two or more fine pulses for a subset of multiple levels of memory cells being programmed) for other portions of the memory that are associated with the reliability risk. For example, in response to receiving a program command from a host device, a memory device may determine whether a portion of a memory to be programmed is associated with a reliability risk. For example, certain portions of a memory may exhibit poorer data retention as a number of PECs associated with the memory increases. Accordingly, the memory device may determine a PEC count associated with the portion of the memory, among other examples. Based on the PEC count and/or a similar parameter, the memory device may determine if the portion of the memory is associated with a reliability risk, such as by using one or more lookup tables associated with PEC thresholds. If the portion of the memory is not associated with a reliability risk, the memory device may execute the program command using a single-fine program scheme, thereby reducing power consumption and program time as compared to partial-fine program schemes. However, if the portion of the memory is associated with a reliability risk, the memory device may execute the program command using a partial-fine program scheme, which may be a program scheme associated with performing multiple fine pulses for only a subset (e.g., less than all) of the multiple levels of cells being programmed, thereby improving data retention for reliability-risk cells as compared to single-fine program schemes.

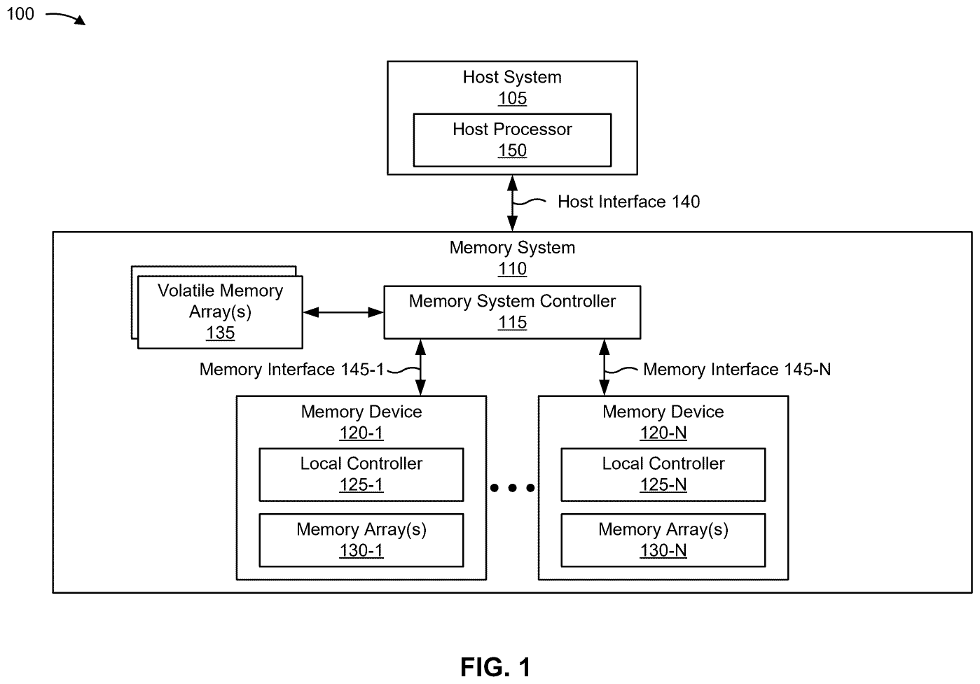

FIG. 1 is a diagram illustrating an example system 100 capable of performing a partial-fine program scheme for reliability risk word lines. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N (where N≥1). A memory device may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N (where N≥1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a double data rate (DDR) interface, and/or a DIMM interface.

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller. Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

In some implementations, one or more systems, devices, apparatuses, components, and/or controllers of FIG. 1 may be configured to receive, from a host device, a program command instructing the memory device to program host data to a portion of a memory; determine whether the portion of the memory is associated with a reliability risk; determine, based on whether the portion of the memory is associated with the reliability risk, a selected program scheme to be used to program the host data to the portion of the memory, wherein the selected program scheme is one of a single-fine program scheme or a partial-fine program scheme, wherein the single-fine program scheme includes performing a fine pulse for each level of cells being programmed, of multiple levels of cells being programmed, and wherein the partial-fine program scheme includes performing multiple fine pulses for only a subset of the multiple levels of cells being programmed; and execute the program command by performing the selected program scheme.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

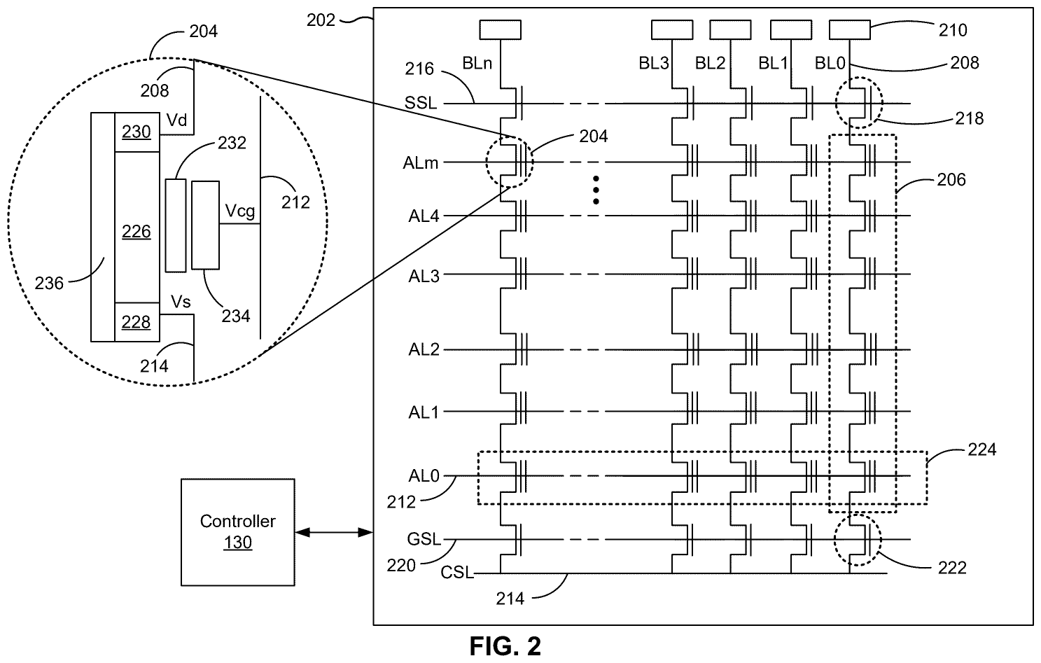

FIG. 2 is a diagram of example components included in a memory device 120. As described above in connection with FIG. 1, the memory device 120 may include a local controller 125 and memory arrays 130. As shown in FIG. 2, the memory device 120 may include a memory array 202, which may correspond to the memory array 130 described above in connection with FIG. 1.

In FIG. 2, the memory array 202 is a NAND memory array. However, in some implementations, the memory array 202 may be another type of memory array, such as a NOR memory array, a resistive RAM (RRAM) memory array, a magnetoresistive RAM (MRAM) memory array, a ferroelectric RAM (FeRAM) memory array, a spin-transfer torque RAM (STT-RAM) memory array, a phase-change memory (PCM) array, or the like. In some implementations, the memory array 202 is part of a three-dimensional stack of memory arrays, such as 3D NAND flash memory, 3D NOR flash memory, or the like.

The memory array 202 includes multiple memory cells 204. A memory cell 204 may store an analog value, such as an electrical voltage or an electrical charge, that represents a data state (e.g., a digital value). The analog value and corresponding data state depend on a quantity of electrons trapped or present within a region of the memory cell 204 (e.g., in a charge trap, such as a floating gate), as described below.

A NAND string 206 (sometimes called a string) may include multiple memory cells 204 connected in series. A NAND string 206 is coupled to a bit line 208 (sometimes called a digit line or a column line, and shown as BL0-BLn). Data can be read from or written to the memory cells 204 of a NAND string 206 via a corresponding bit line 208 using one or more input/output (I/O) components 210 (e.g., an I/O circuit, an I/O bus, a page buffer, and/or a sensing component, such as a sense amplifier). Memory cells 204 of different NAND strings 206 (e.g., one memory cell 204 per NAND string 206) may be coupled with one another via access lines 212 (sometimes called word lines or row lines, and shown as AL0-ALm) that select which row (or rows) of memory cells 204 is affected by a memory operation (e.g., a read operation or a write operation).

A NAND string 206 may be connected to a bit line 208 at one end and a common source line (CSL) 214 at the other end. A string select line (SSL) 216 may be used to control respective string select transistors 218. A string select transistor 218 selectively couples a NAND string 206 to a corresponding bit line 208. A ground select line (GSL) 220 may be used to control respective ground select transistors 222. A ground select transistor 222 selectively couples a NAND string 206 to the common source line 214.

A “page” of memory (or “a memory page”) may refer to a group of memory cells 204 connected to the same access line 212, as shown by reference number 224. In some implementations (e.g., for single-level cells), the memory cells 204 connected to an access line 212 may be associated with a single page of memory. In some implementations (e.g., for multi-level cells), the memory cells 204 connected to an access line 212 may be associated with multiple pages of memory, where each page represents one bit stored in each of the memory cells 204 (e.g., a lower page that represents a first bit stored in each memory cell 204 and an upper page that represents a second bit stored in each memory cell 204). In NAND memory, a page is the smallest physically addressable data unit for a write operation (sometimes called a program operation).

In some implementations, a memory cell 204 is a floating-gate transistor memory cell. In this case, the memory cell 204 may include a channel 226, a source region 228, a drain region 230, a floating gate 232, and a control gate 234. The source region 228, the drain region 230, and the channel 226 may be on a substrate 236 (e.g., a semiconductor substrate). The memory device 120 may store a data state in the memory cell 204 by charging the floating gate 232 to a particular voltage associated with the data state and/or to a voltage that is within a range of voltages associated with the data state. This results in a predefined amount of current flowing through the channel 226 (e.g., from the source region 228 to the drain region 230) when a specified read voltage is applied to the control gate 234 (e.g., by a corresponding access line 212 connected to the control gate 234). Although not shown, a tunnel oxide layer (or tunnel dielectric layer) may be interposed between the floating gate 232 and the channel 226, and a gate oxide layer (e.g., a gate dielectric layer) may be interposed between the floating gate 232 and the control gate 234. As shown, a drain voltage Vd may be supplied from a bit line 208, a control gate voltage Veg may be supplied from an access line 212, and a source voltage Vs may be supplied via the common source line 214 (which, in some implementations, is a ground voltage).

To write or program the memory cell 204, Fowler-Nordheim tunneling may be used. For example, a strong positive voltage potential may be created between the control gate 234 and the channel 226 (e.g., by applying a large positive voltage to the control gate 234 via a corresponding access line 212) while current is flowing through the channel 226 (e.g., from the common source line 214 to the bit line 208, or vice versa). The strong positive voltage at the control gate 234 causes electrons within the channel 226 to tunnel through the tunnel oxide layer and be trapped in the floating gate 232. These negatively charged electrons then act as an electron barrier between the control gate 234 and the channel 226 that increases the threshold voltage of the memory cell 204. The threshold voltage is a voltage required at the control gate 234 to cause current (e.g., a threshold amount of current) to flow through the channel 226. Fowler-Nordheim tunneling is an example technique for storing a charge in the floating gate, and other techniques, such as channel hot electron injection, may be used.

To read the memory cell 204, a read voltage may be applied to the control gate 234 (e.g., via a corresponding access line 212), and an I/O component 210 (e.g., a sense amplifier) may determine the data state of the memory cell 204 based on whether current passes through the memory cell 204 (e.g., the channel 226) due to the applied voltage. A pass voltage may be applied to all memory cells 204 (other than the memory cell 204 being read) in the same NAND string 206 as the memory cell 204 being read. For example, the pass voltage may be applied on each access line 212 other than the access line 212 of the memory cell 204 being read (e.g., where the read voltage is applied). The pass voltage is higher than the highest read voltage associated with any memory cell data states so that all of the other memory cells 204 in the NAND string 206 conduct, and the I/O component 210 can detect a data state of the memory cell 204 being read by sensing current (or lack thereof) on a corresponding bit line 208. For example, in a single-level memory cell that stores one of two data states, the data state is a “1” if current is detected, and the data state is a “0” if current is not detected. In a multi-level memory cell that stores one of three or more data states, multiple read voltages are applied, over time, to the control gate 234 to distinguish between the three or more data states and determine a data state of the memory cell 204.

To erase the memory cell 204, a strong negative voltage potential may be created between the control gate 234 and the channel 226 (e.g., by applying a large negative voltage to the control gate 234 via a corresponding access line 212). The strong negative voltage at the control gate 234 causes trapped electrons in the floating gate 232 to tunnel back across the oxide layer from the floating gate 232 to the channel 226 and to flow between the common source line 214 and the bit line 208. This removes the electron barrier between the control gate 234 and the channel 226 and decreases the threshold voltage of the memory cell 204 (e.g., to an empty or erased state, which may represent a “1”). In NAND memory, a block is the smallest unit of memory that can be erased. A block of NAND memory includes multiple pages. Thus, an individual page of a block cannot be erased without erasing every other page of the block. In some implementations, a block may be divided into multiple sub-blocks. A sub-block is a portion of a block and may include a subset of pages of the block and/or a subset of memory cells of the block.

As indicated above, FIG. 2 is provided as an example. Other examples may differ from what is described with regard to FIG. 2.

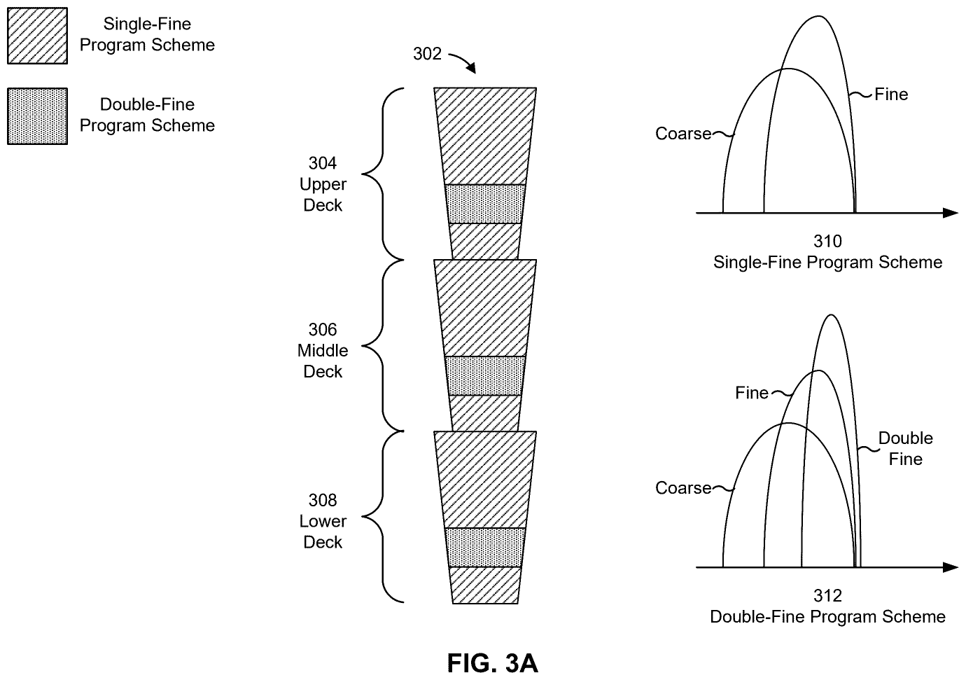

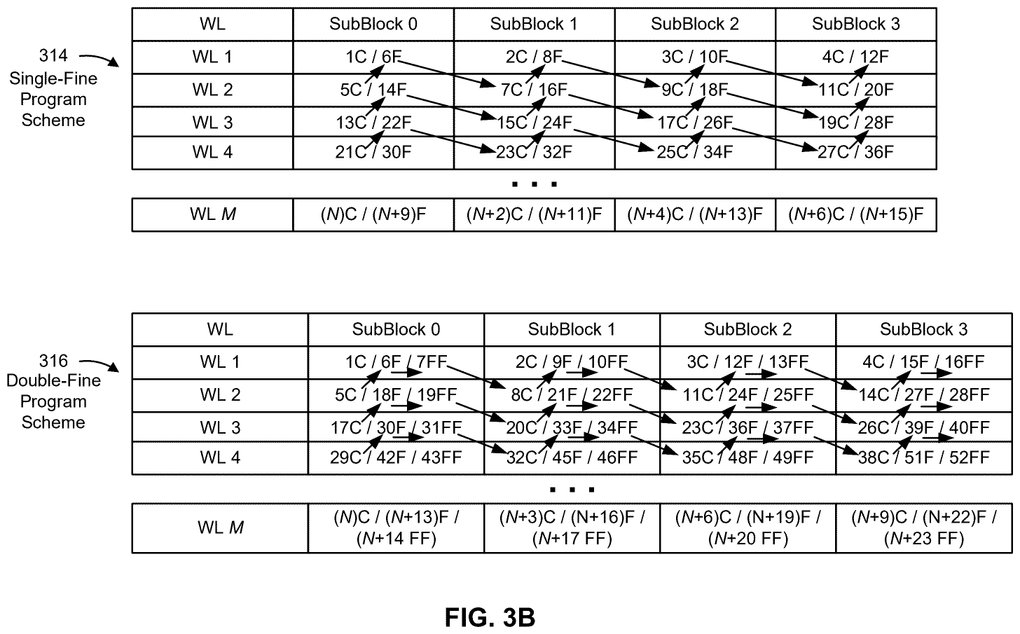

FIGS. 3A-3B are diagrams of examples associated with multi-fine program schemes for reliability risk word lines. The operations described in connection with FIGS. 3A-3B may be performed by the memory device 120 and/or one or more components of the memory device 120, such as the local controller 125 and/or one or more components of the local controller 125.

As shown in FIG. 3A, and as indicated by reference number 302, a memory (e.g., memory array 130) may be associated with a three-dimensional architecture, sometimes referred to as a multi-deck memory architecture. The example multi-deck memory architecture shown in FIG. 3A is a three-deck memory architecture including an upper deck 304, a middle deck 306, and a lower deck 308, but, in some other implementations, a multi-deck memory architecture may include a different number of decks (e.g., two decks or more than three decks).

In some implementations, due to the geometry of the multi-deck memory architecture (e.g., due to a geometry of a central pillar of the multi-deck memory) and/or due to other factors (e.g., due to varying word-line resistances in the multi-deck memory), certain portions of the multi-deck memory architecture may exhibit poor data retention capabilities and/or may otherwise be associated with a reliability risk. For example, word lines located near a top of a deck and/or a bottom of a deck may have poor reliability as compared to word lines located elsewhere in the deck. Accordingly, in some implementations, a multi-fine program scheme (e.g., a double-fine program scheme, a triple-fine program scheme, or another multi-fine program scheme) may be used for the portions of each deck that pose a reliability risk. For example, as indicated using stippling in FIG. 3A, most word lines of each deck may not be associated with a reliability risk, and thus a single-fine program scheme may be used when writing host data to those word lines. As indicated by reference number 310, the single-fine program scheme may use two voltage passes and/or pulses to set a voltage level of each memory cell. During a first pass and/or pulse (e.g., a coarse pulse), a voltage level of a memory cell may be set to a general proximity of a final program voltage. During a second pass and/or pulse (e.g., a fine pulse), a voltage applied to the memory cell may be more concentrated and/or fine-tuned in order to set the voltage level of the memory cell to the final program voltage.

Moreover, as indicated using cross-hatching in FIG. 3A, certain word lines of each deck may be associated with a reliability risk, and thus a multi-fine program (e.g., a double-fine program scheme, a triple-fine program scheme, or the like) may be used when writing host data to those word lines. As indicated by reference number 312, a double-fine program scheme may use three voltage passes and/or pulses to set a voltage level of each memory cell. During a first pass and/or pulse (e.g., a coarse pulse), a voltage level of a memory cell may be set to a general proximity of a final program voltage. During a second pass and/or pulse (e.g., a fine pulse), a voltage applied to the memory cell may be more concentrated and/or fine-tuned in order to set the voltage level of the memory cell very near to the final program voltage. And during a third pass and/or pulse (sometimes referred to herein as a double fine pulse), a voltage applied to the memory cell may be even more concentrated and/or fine-tuned in order to set the voltage level of the memory cell to the final program voltage. For triple-fine program schemes, quad-fine program schemes, or other multi-fine program schemes, additional fine pulses may be implemented (e.g., a triple fine pulse for triple-fine program schemes, a triple fine pulse and a quad-fine pulse for quad-fine program schemes, and so forth).

FIG. 3B shows example tables indicating programming sequences associated with a single-fine program scheme and a double-fine program scheme. More particularly, reference number 314 shows a table indicating an example programming sequence associated with a single-fine program scheme, such as the single-fine program scheme described above in connection with reference number 310, and reference number 316 shows a table indicating an example programming sequence associated with a double-fine program scheme, such as the double-fine program scheme described above in connection with reference number 312. In the tables indicated by reference numbers 314 and 316, an order of a program operation is shown using a numeral (e.g., “1” for the first program operation to be performed by a memory device, “2” for the second program operation to be performed by the memory device, and so forth), and a type of programming pulse to be performed at each operation is shown using letters (e.g., “C” for a coarse pulse, “F” for a fine pulse, and “FF” for a double fine pulse).

As shown in the single-fine program scheme table indicated by reference number 314, for a first word line to be programmed (indexed as “WL 1” in FIG. 3B), the memory device may perform a coarse pulse on each subblock to be programmed (indexed as subblock 0 through subblock 3 in FIG. 3B). More particularly, the memory device may first perform a coarse pulse on subblock 0 (shown as “1C”), may next perform a coarse pulse on subblock 1 (shown as “2C”), and so forth through subblock 3 (shown as “4C”). The memory device may then perform a coarse pulse on a first subblock (e.g., subblock 0) of the next word line to be programmed (e.g., WL 2), shown as “5C.” Rather than performing a coarse pulse on each subblock of the second word line, however, the memory device may next perform a fine pulse on a first subblock of the first word line (e.g., WL 1), shown as “6F.” In this regard, for the second and subsequent word lines to be programmed, the memory device may perform multiple programming pulses (e.g., a coarse pulse on an M-th word line of the subblock, and a fine pulse on an (M−1)-th word line of the subblock), prior to performing operations on a next subblock of the M-th word line. In some implementations, performing program operations in this sequence may be referred to herein as a subblock-first program sequence.

After performing the fine pulse on the first word line (e.g., WL 1) associated with the first subblock (e.g., subblock 0), the memory device may proceed with performing a coarse pulse on the second word line (e.g., WL 2) in the second subblock (e.g., subblock 1) as indicated by “7C,” performing a fine pulse on the first word line (e.g., WL 1) in the second subblock (e.g., subblock 1) as indicated by “8F,” and so forth as indicated using arrows in the single-fine program scheme table indicated by reference number 314. More generally, for the second and subsequent word lines, for a given word line M, the first subblock (e.g., subblock 0) may be associated with an N-th coarse pulse and an (N+9)-th fine pulse, the second subblock (e.g., subblock 1) may be associated with an (N+2)-th coarse pulse and an (N+11)-th fine pulse, the third subblock (e.g., subblock 2) may be associated with an (N+4)-th coarse pulse and an (N+13)-th fine pulse, and the fourth subblock (e.g., subblock 3) may be associated with an (N+6)-th coarse pulse and an (N+15)-th fine pulse, and so forth.

In some implementations, the double-fine program scheme may be associated with a similar subblock-first program scheme, but one that uses two fine pulses instead of one fine pulse. More particularly, as shown in the double-fine program scheme table indicated by reference number 316, for a first word line to be programmed (e.g., WL 1), the memory device may perform a coarse pulse on each subblock to be programmed, such as a coarse pulse on subblock 0 (shown as “1C”), a coarse pulse on subblock 1 (shown as “2C”), and so forth through subblock 3 (shown as “4C”). The memory device may then perform a coarse pulse on a first subblock (e.g., subblock 0) of the next word line to be programmed (e.g., WL 2), shown as “5C.” The memory device may then perform a fine pulse on a first subblock of the first word line (e.g., WL 1), shown as “6F,” as well as a double fine pulse on the first subblock of the first word line, shown as “7FF.” In this regard, for the second and subsequent word lines to be programmed, the memory device may perform multiple programming pulses (e.g., a coarse pulse on an M-th word line of the subblock, a fine pulse on an (M−1)-th word line of the subblock, and a double fine pulse on the (M−1)-th word line of the subblock), prior to moving to a next subblock (e.g., the memory device may use a subblock-first program scheme).

After performing the fine pulse and the double fine pulse on the first word line (e.g., WL 1) associated with the first subblock (e.g., subblock 0), the memory device may proceed with performing a coarse pulse on the second word line (e.g., WL 2) in the second subblock (e.g., subblock 1) as indicated by “8C,” performing a fine pulse and a double fine pulse on the first word line (e.g., WL 1) in the second subblock (e.g., subblock 1) as indicated by “9F” and “10FF,” respectively, and so forth as indicated using arrows in the double-fine program scheme table indicated by reference number 316. More generally, for the second and subsequent word lines, for a given word line M, the first subblock (e.g., subblock 0) may be associated with an N-th coarse pulse, an (N+13)-th fine pulse, and an (N+14)-th double fine pulse; the second subblock (e.g., subblock 1) may be associated with an (N+3)-th coarse pulse, an (N+16)-th fine pulse, and an (N+17)-th double fine pulse; the third subblock (e.g., subblock 2) may be associated with an (N+6)-th coarse pulse, an (N+19)-th fine pulse, and an (N+20)-th double fine pulse; and the fourth subblock (e.g., subblock 3) may be associated with an (N+9)-th coarse pulse, an (N+22)-th fine pulse, and an (N+23)-th double fine pulse.

Using a single-fine program scheme, such as the single-fine program scheme shown in connection with reference number 310 and/or described in connection with the program sequence table indicated by reference number 314, to program a majority of the word lines of the memory may result in reduced power consumption as compared to implementations in which a multi-fine program scheme is used for all word lines in a memory deck, because fewer fine voltage passes are needed to set a final program voltage of each memory cell. Moreover, selectively implementing a multi-fine program scheme, such as the double-fine program scheme shown in connection with reference number 312 and/or described in connection with the program sequence table indicated by reference number 316, to program reliability-risk word lines of the memory may result in increased reliability as compared to implementations in which a single-fine program scheme is used for all word lines in a memory deck, because the additional fine voltage passes at the reliability-risk word lines may improve an RWB associated with the reliability-risk word lines and/or may improve data retention of the reliability-risk word lines. For example, using a multi-fine program scheme for reliability-risk word lines may result in more accurate and/or tightly concentrated program voltages, thereby improving an RWB associated with the memory. However, implementing a multi-fine program scheme may result in increased resource consumption and long programming times, because each cell being programmed using a multi-fine program scheme may be subject to multiple programming pulses, among other operations.

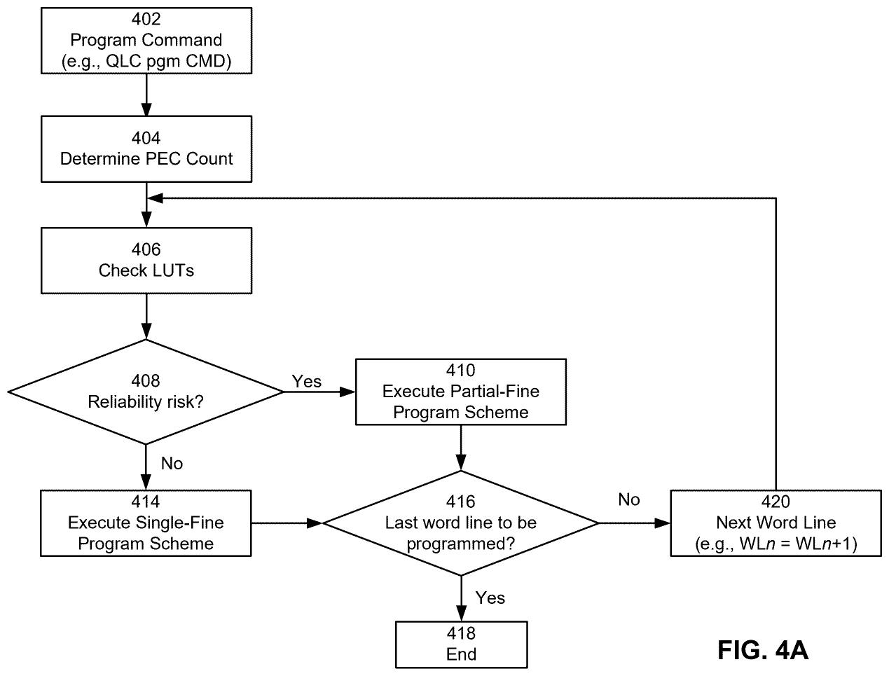

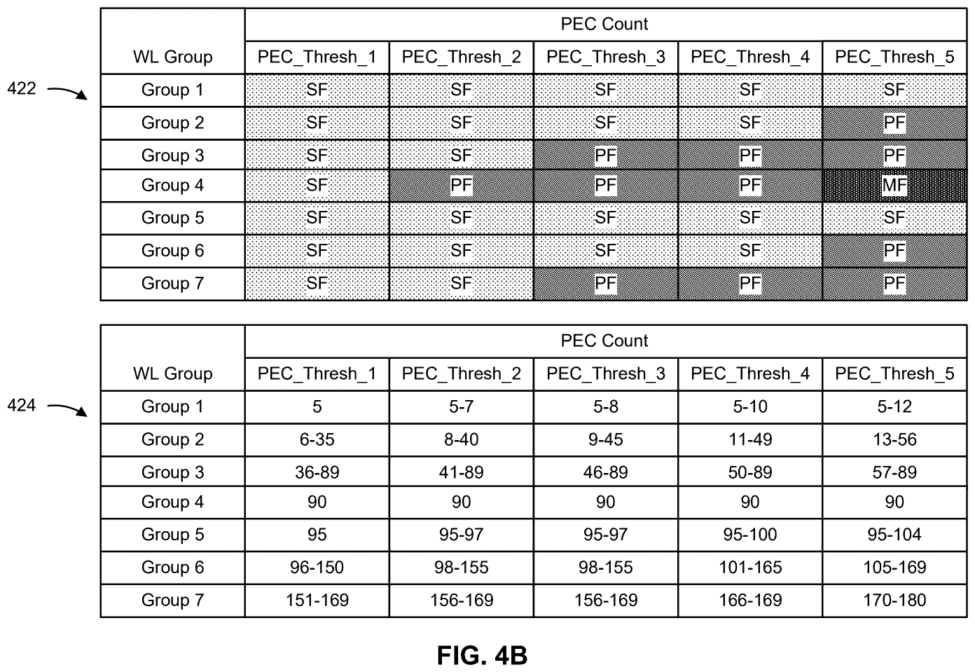

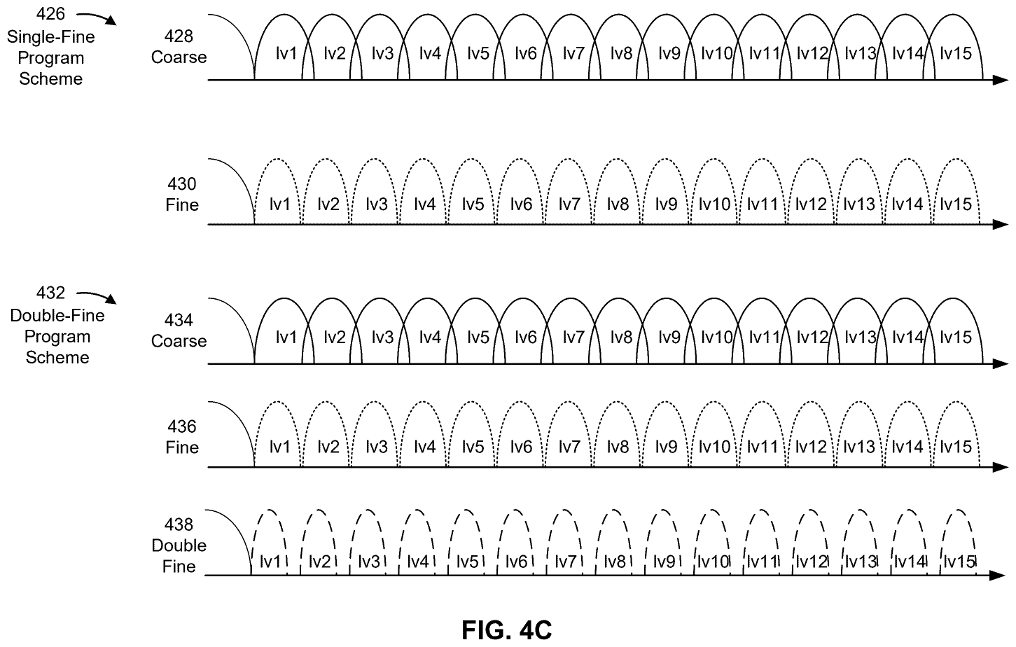

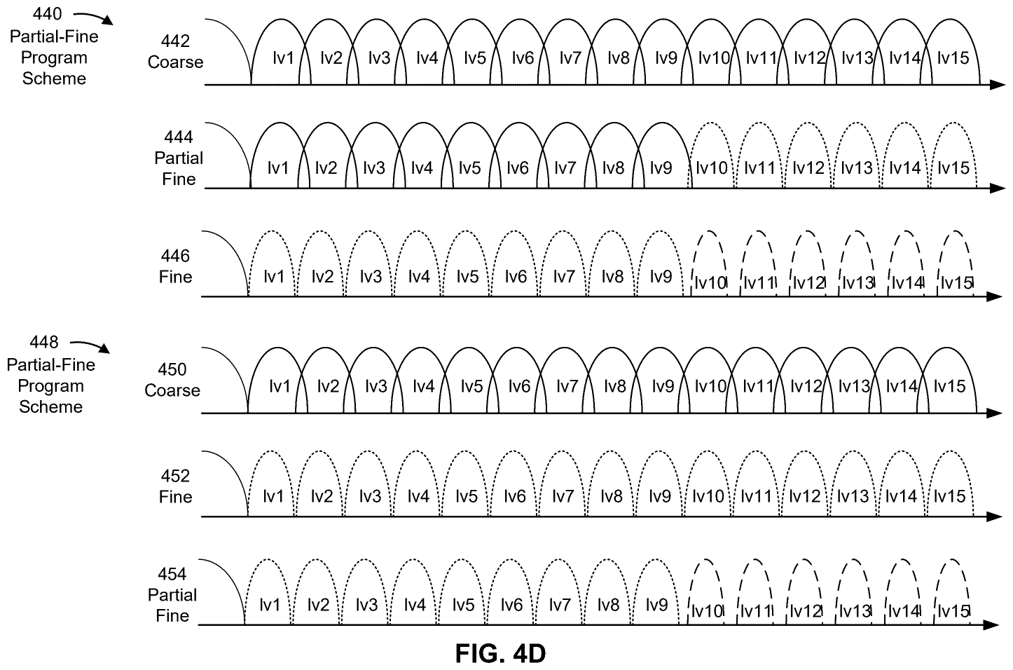

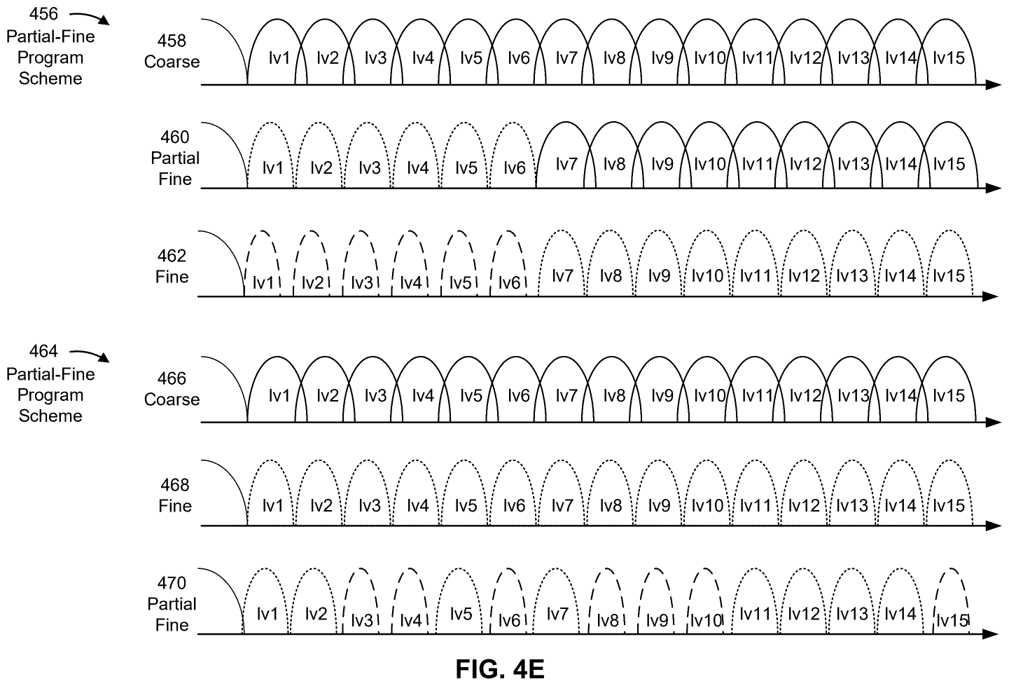

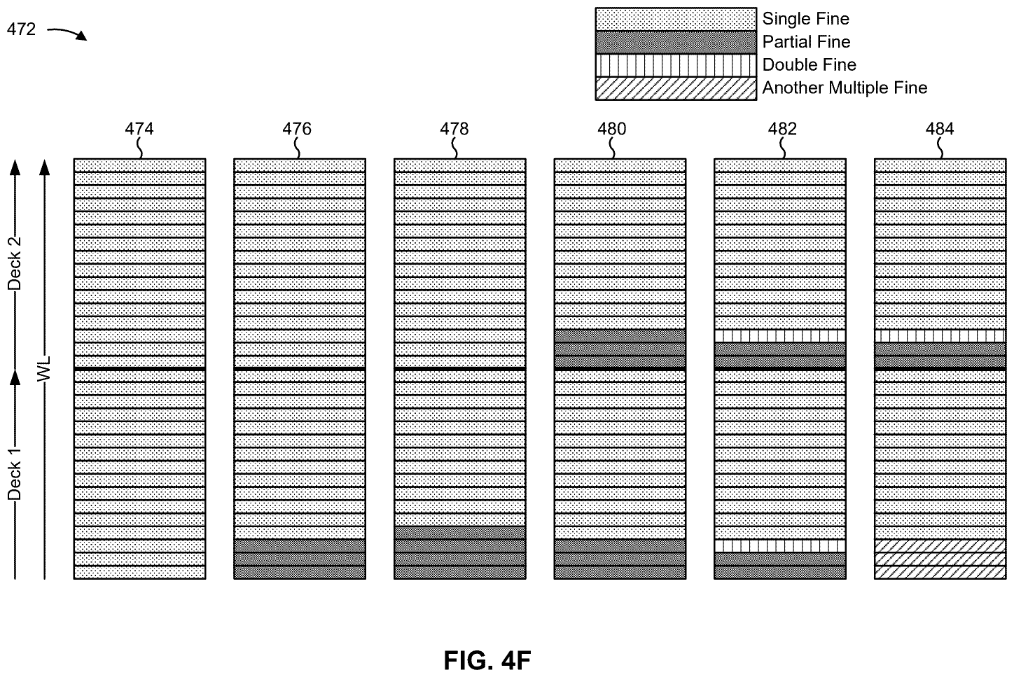

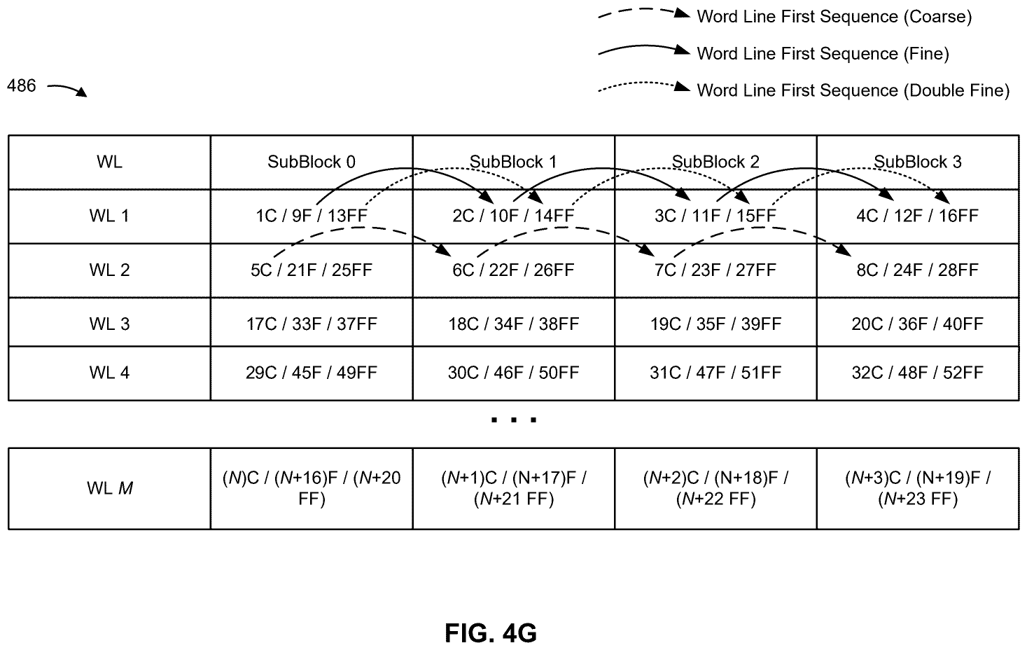

Some implementations and techniques described herein may enable increased reliability for memory devices as compared to implementations in which only a single-fine program scheme is implemented while enabling decreased resource consumption and/or program times as compared to implementations in which multi-fine program scheme is implemented for reliability-risk word lines, or the like. More particularly, some implementations described herein may enable a partial-fine program scheme, in which multiple programming pulses are used for a subset (e.g., less than all) of levels of memory cells being programmed. In some implementations, a memory device may selectively implement a single-fine program scheme for portions of a memory that are not associated with a reliability risk, while implementing a partial-fine program scheme (e.g., a program scheme that uses two or more fine pulses for a subset of multiple levels of memory cells being programmed) for other portions of the memory that are associated with the reliability risk. For example, in response to receiving a program command from a host device, a memory device may determine whether a portion of a memory to be programmed is associated with a reliability risk. For example, certain portions of a memory may exhibit poorer data retention as a number of PECs associated with the memory increases. Accordingly, the memory device may determine a PEC count associated with the portion of the memory, among other examples. Based on the PEC count, and/or a similar parameter, the memory device may determine if the portion of the memory is associated with a reliability risk, such as by using one or more lookup tables associated with PEC thresholds. If the portion of the memory is not associated with a reliability risk, the memory device may execute the program command using a single-fine program scheme, thereby reducing power consumption and program time as compared to multi-fine program schemes (e.g., double-fine program schemes). However, if the portion of the memory is associated with a reliability risk, the memory device may execute the program command using a partial-fine program scheme, which may be a program scheme associated with performing multiple fine pulses for only a subset (e.g., less than all) of the multiple levels of cells being programmed (e.g., levels of the cells that may pose the highest reliability risk), thereby improving data retention as compared to single-fine program schemes while decreasing power consumption and/or programming time as compared to multi-fine program schemes. This may be more readily understood with reference to FIGS. 4A-4G.

As indicated above, FIGS. 3A-3B are provided as examples. Other examples may differ from what is described with regard to FIGS. 3A-3B.

FIGS. 4A-4G are diagrams of examples associated with a partial-fine program scheme for reliability risk word lines. The operations described in connection with FIGS. 4A-4B may be performed by the memory system 110 and/or one or more components of the memory system 110, such as the memory system controller 115, one or more memory devices 120, and/or one or more local controllers 125.

More particularly, FIG. 4A shows example operations that may be performed by a memory device (e.g., memory device 120) to selectively implement a partial-fine program scheme for reliability-risk word lines. As shown in FIG. 4A, and as indicated by reference number 402, the memory device may receive, from a host device (e.g., host system 105), a program command instructing the memory device to program host data to a portion of a memory (e.g., a portion of the memory array 130). For example, the program command may instruct the memory device to program the host data to a group of word lines (e.g., access lines 212) associated with the memory. In some implementations, the program command may be associated with a QLC program command (e.g., a program command that instructs the memory device to write the host data to QLC memory). QLC memory may be memory for which each memory cell is capable being programmed to one of sixteen data states, such as for a purpose of storing four bits of data. For example, a cell of a QLC memory may be left uncharged (corresponding to a first data state, of the sixteen data states) or may be programmed to one of fifteen levels (sometimes referred to herein as level 1 through level 15, with each level corresponding to a second through sixteenth data states, of the sixteen data states). In such implementations, certain word lines associated with the QLC program command may pose a reliability risk as described above, such as due to a limited RWB of QLC memory as compared to other types of memory (e.g., a multi-level (MLC) memory, a triple-level cell (TLC) memory, a penta-level cell (PLC) memory, or the like). However, in some other implementations, the program command and/or the memory may be associated with a different type of memory, such as a TLC memory, a PLC memory, and/or a similar type of memory.

In some implementations, the memory device may determine whether the portion of the memory to be programmed is associated with a reliability risk. For example, the memory device may determine whether a word line being programmed is associated with a reliability risk based on a PEC count associated with the word line, such as by whether the PEC count satisfies a certain threshold. In such implementations, and as indicated by reference number 404, the memory device may determine a PEC count associated with the portion of the memory (e.g., a word line to be programmed). The memory device (e.g., a controller of the memory device) may track and/or determine a PEC count using any conventional method. In some implementations, the memory device may store a PEC count locally (e.g., in a NAND cell) and may thus read the PEC count locally when the PEC count is needed (e.g., when the memory device is performing the operations shown in connection with reference number 404). Put another way, in some implementations, a reliability of certain word lines may be dependent on a quantity of PECs associated with the memory or the like, as described above. Accordingly, the memory device may determine a PEC count associated with the portion of the memory (e.g., a word line to be programmed), such as for a purpose of making a determination as to whether the portion of the memory poses a reliability risk given the current PEC count, among other examples. In some other implementations, the memory device may determine whether the portion of the memory to be programmed is associated with a reliability risk based on other characteristics and/or factors (e.g., operating conditions such as an ambient temperature of the memory device, and/or a physical location of the word line in a memory array, among other examples) without departing from the scope of the disclosure.

In some implementations, the memory device may make a determination as to whether the portion of the memory poses a reliability risk given the current PEC count and/or other characteristics based on referencing a data structure, such as a lookup table or a similar structure. In such implementations, and as indicated by reference number 406, the memory device may check one or more lookup tables to determine if a word line to be programmed is indicated as being associated with a partial-fine program scheme and/or another program scheme (e.g., a double-fine program scheme and/or another multi-fine program scheme) for the corresponding PEC count, among other examples. For example, a lookup table may indicate a program scheme to be used for each of multiple groups of word lines for a given PEC threshold, or the like. Aspects of various lookup tables that a memory device may reference in connection with operations described in connection with reference number 406 are described in more detail below in connection with FIG. 4B.

As indicated by reference number 408, the memory device may determine, based on the PEC count and/or other characteristics, whether the portion of the memory is associated with a reliability risk, and/or the memory device may determine, based on whether the portion of the memory is associated with the reliability risk, a selected program scheme to be used to program the host data to the portion of the memory. For example, the memory device may determine if a word line to be programmed to is a word line that is specified (e.g., by a lookup table or similar data structure) as being associated with a partial-fine program scheme. If the memory device determines that a word line to be programmed to is a reliability risk (e.g., the word line is one that is specified as being associated with a partial-fine program scheme in a lookup table or the like), the memory device may select a partial-fine program scheme to execute the program command, examples of which are described in more detail below in connection with FIGS. 4C-4E. On the other hand, if the memory device determines that a word line to be programmed to is not a reliability risk (e.g., the word line is not one that is specified as being associated with a partial-fine program scheme in a lookup table or the like), the memory device may select the single-fine program scheme to execute the program command.

As indicated by reference numbers 410 and 414, the memory device may execute the program command by performing the selected program scheme. More particularly, as indicated by reference number 410, when the word line to be programmed to is a reliability risk (e.g., the word line is one that is specified as being associated with a partial-fine program scheme in a lookup table or the like), the memory device may execute the partial-fine program scheme, such as one of the partial-final program schemes described in more detail below in connection with FIGS. 4C-4E. As indicated by reference number 414, when the word line to be programmed to is not a reliability risk (e.g., the word line is not one that is specified as being associated with a partial-fine program scheme in a lookup table or the like), the memory device may execute the single-fine program scheme.

As indicated by reference number 416, the memory device may determine whether additional word lines are to be programmed in connection with the program command. As shown by reference number 418, when no additional word lines are to be programmed (e.g., when a final word line has been programmed by the memory device), the operations may end. However, as indicated by reference number 420, when more word lines are to be programmed (e.g., when another word line associated with the program command, sometimes referred to as WLn+1, is to be programmed after the current word line being programmed, sometimes referred to as WLn), the memory device may perform one or more of the operations for the next word line, including checking a lookup table to determine if the word line (e.g., WLn+1) is specified as being associated with a partial-fine program scheme given the PEC count and/or other characteristics, and executing one of the single-fine program scheme or the partial-fine program scheme, accordingly.

FIG. 4B shows example lookup tables that may be used by a memory device to selectively implement one of a single-fine program scheme or a partial-fine program scheme, such as in implementations in which the memory device selectively implements one of a single-fine program scheme or a partial-fine program scheme based on a PEC count associated with the memory. For example, as indicated by reference number 422, in some implementations a lookup table may indicate multiple PEC count thresholds (shown in FIG. 4B as a first PEC count threshold, PEC_Thresh_1, through a fifth PEC count threshold, PEC_Thresh_5) and, for each PEC count threshold, of the multiple PEC count thresholds, a corresponding program scheme for each of multiple word line groups (shown in FIG. 4B as a first word line group, Group 1, through a seventh word line group, Group 7).

More particularly, at each PEC count threshold, the lookup table may indicate whether a single-fine program scheme (shown in FIG. 4B as “SF”), a partial-fine program scheme (shown in FIG. 4D as “PF”), or a multi-fine program scheme (shown in FIG. 4B as “MF”), such as a double-fine program scheme and/or another multi-fine program scheme (e.g., a triple-fine program scheme), should be used to program data to word lines in the various word line groups. Thus, when determining which program scheme is to be used to execute a program command at a given word line, the memory device may determine a PEC count associated with the memory (as described above in connection with reference number 404) and/or may identify a program scheme associated with a word line group that includes the word line for a corresponding PEC count threshold (e.g., a highest threshold, of the multiple PEC count thresholds, that is satisfied by the PEC count). For example, if a memory device determines that a PEC count associated with the memory satisfies the fourth PEC count threshold (PEC_Thresh_4) but not the fifth PEC count threshold (PEC_Thresh_5), the memory device may determine a program scheme using the column under the heading “PEC_Thresh_4.” In that regard, if a word line being programmed (e.g., WLn) is in Group 2, the memory device may thus use a single-fine program scheme (as indicated by “SF” in the cell corresponding to PEC_Thresh_4 and Group 2). Similarly, if a word line being programmed is in Group 4, the memory device may thus use a partial-fine program scheme (as indicated by “PF” in the cell corresponding to PEC_Thresh_4 and word Group 2).

Moreover, in some implementations, a multi-fine program scheme (e.g., a double-fine program scheme, a triple-fine program scheme, or another multi-fine program scheme) may be implemented for word line groups associated with a high reliability risk and/or for high PEC counts. For example, in the implementation indicated by reference number 422, if a word line being programmed (e.g., WLn) is in Group 4 and the memory device determines that a PEC count associated with the memory satisfies the fifth PEC count threshold (PEC_Thresh_5), the memory device may use a multi-fine program scheme (as indicated by “MF” in the cell corresponding to PEC_Thresh_5 and Group 4). This may correspond to a word line group that poses a higher risk of data loss due to a location within a memory (e.g., near a bottom or a top of a deck of memory), among other examples.

As indicated in the lookup table shown by reference number 422, for higher PEC count thresholds, more word line groups may be subject to a partial-fine program scheme as compared to lower PEC count thresholds, which may be reflective of certain word lines posing an increased reliability risk as a PEC count increases (e.g., due to dielectric degradation, or the like). More particularly, at the first PEC count threshold (e.g., PEC_Thresh_1), each word line group may be associated with a single-fine program scheme. However, at the fifth PEC count threshold (e.g., PEC_Thresh_5), only two word line groups are associated with the single-fine program scheme (e.g., Group 1 and Group 5). The remaining word line groups may be associated with a partial-fine program scheme or a multi-fine program scheme (e.g., either a double-fine program scheme or a triple-fine program scheme). More particularly, Groups 2, 3, 6, and 7 may be associated with a partial-fine program scheme, and Group 4 may be associated with a multi-fine program scheme. In that regard, a given word line may be associated with various program schemes at different PEC count thresholds. For example, a certain word line (e.g., a word line in Group 4) may be associated with a single-fine program scheme when a corresponding PEC count satisfies one PEC count threshold (e.g., PEC_Thresh_1_), a partial-fine program scheme when the corresponding PEC count satisfies another PEC threshold (e.g., PEC_Thresh_2), and a multi-fine program scheme when the corresponding PEC count satisfies yet another PEC threshold (e.g., PEC_Thresh_5).

In some implementations, a set of one or more word lines included in each group of word lines (e.g., each of Group 1 through Group 7) may be the same at each PEC count threshold, while, in some other implementations, a set of one or more word lines included in each group of word lines may differ at different PEC count thresholds. Put another way, a given word line group may be associated with a first set of one or more word lines at a first PEC count threshold and may be associated with a second set of one or more word lines, that is different from the first set of one or more word lines, at a second PEC count threshold.

For example, reference number 424 shows a lookup table that associates the various PEC count thresholds with sets of word lines in each word line group. For at least some of the word line groups, a set of word lines associated with the word line group may differ at different PEC count thresholds. For example, Group 3 may include word lines indexed as 36-89 at the first PEC count threshold (e.g., PEC_Thresh_1), word lines indexed as 41-89 at the second PEC count threshold (e.g., PEC_Thresh_2), word lines indexed as 46-89 at the third PEC count threshold (e.g., PEC_Thresh_3), word lines indexed as 50-89 at the fourth PEC count threshold (e.g., PEC_Thresh_4), and word lines indexed as 57-89 at the fifth PEC count threshold (e.g., PEC_Thresh_5). In this regard, a set of word lines within a specific word line group may differ as a function of PEC count, which may enable accommodation of more word lines that are subject to partial-fine program schemes and/or multi-fine program schemes at higher PEC counts.

By using one of the lookup tables described above in connection with FIG. 4B and/or a similar lookup table or data structure, the memory device may be configured to selectively implement one of multiple candidate program schemes based on a reliability risk category associated with a word line being programmed (e.g., one of a low reliability risk category corresponding to using a single-fine program scheme, a medium reliability risk category corresponding to using a double-fine program scheme, or a high reliability risk category corresponding to using a triple-fine program scheme). Put another way, when determining whether a portion of a memory to be programmed to is associated with a reliability risk and/or when determining a selected program scheme to be used to program host data to the portion of the memory (e.g., as described above in connection with reference number 408), the memory device may be configured to select the single-fine program scheme when the portion of the memory is associated with a first reliability risk category (e.g., a low reliability risk category), select a partial-fine program scheme when the portion of the memory is associated with a second reliability risk category (e.g., a medium reliability risk category), and/or select a multi-fine program scheme (e.g., a double-fine program scheme, a triple-fine program scheme, or the like) when the portion of the memory is associated with a third reliability risk category (e.g., a high reliability risk category).

FIGS. 4C-4E show different programming pulses that may be used for single-fine program schemes, multi-fine program schemes (e.g., double-fine program schemes), and partial-fine program schemes, according to some implementations. The example program schemes shown in FIGS. 4C-4E are shown and described in connection with a QLC memory (e.g., a memory in which each cell is capable of being programmed to one of sixteen data states), but, in some other implementations, substantially similar operations may be implemented in other types of memory (e.g., TLC memory, PLC memory, among other examples). In operations involving QLC memory, during a program operation a memory cell may be left uncharged, corresponding to a first data state of sixteen potential data states, or else may be charged to one of fifteen levels (shown in FIGS. 4C-4E as “lv1” through “lv15”), corresponding to a second through sixteenth data state, respectively, of the sixteen potential data states.

As shown by reference number 426, in a single-fine program scheme, memory cells may receive two pulses (e.g., a coarse pulse and a fine pulse), in order to set a threshold voltage within one of the voltage distributions shown in FIG. 4C. More particularly, as indicated by reference number 428, during a coarse programming pulse, a memory cell may receive a voltage such that a threshold voltage associated with the cell is selectively raised to be within a voltage distribution shown in solid lines and corresponding to a level to which the cell is to be programmed. For example, for a cell that is to be programmed to level 8, the cell's threshold voltage may be raised to a level such that it falls within the solid-lined curve shown proximate to “lv8.” As indicated by the solid-line curves shown in connection with reference number 428, the threshold voltage distributions may slightly overlap following the coarse pulse.

Accordingly, as shown by reference number 430, each cell to be programmed receive a fine pulse, which may tighten the threshold voltage distributions and thus increase the reliability of the memory, as described above in connection with reference number 310. More particularly, as indicated using dotted-lines in connection with reference number 430, following the fine pulses, the threshold voltages may no longer overlap. For example, following the fine pulse, a cell that is intended to be programmed to level 8 but which falls at a lower end of the level 8 threshold voltage distribution would likely still be read as a level 8 cell due to the tightened threshold voltage distributions as a result of the fine pulse.

As described above in connection with reference number 312, in some implementations, a memory device may utilize additional fine program schemes, such as for a purpose of further tightening threshold voltage distributions for reliability-risk word lines, or the like. For example, as indicated by reference number 432, in a double-fine program scheme, each cell may receive a coarse pulse (as indicated by reference number 434), which may be substantially similar to the coarse pulse described above in connection with reference number 428, and a fine pulse (as indicated by reference number 436), which may be substantially similar to the fine pulse described above in connection with reference number 430. In this implementation, however, each cell may receive an additional fine pulse, shown in FIG. 4C as a double fine pulse, as indicated by reference number 438, which may further tighten the threshold voltage distributions and thus increase the reliability of the memory (e.g., reliability-risk portions of the memory), as described above in connection with reference number 312. More particularly, as indicated using dashed-lines in connection with reference number 438, following the double fine pulses, the threshold voltage distributions may be even narrower, further decreasing the probability that a certain cell will be misread during a read operation or the like.

As can be seen by comparing the single-fine program scheme shown by reference number 426 with the double-fine program scheme indicated by reference number 432, implementing the double-fine program scheme (or another multi-fine program scheme) may result in a programming time and/or resource consumption penalty associated with the second fine programming pass. Accordingly, in some implementations, a partial-fine program scheme may be implemented, which, as described above, may include performing a second fine programming pulse for only a subset of levels of cells being programmed. Put another way, the partial-fine program scheme may include performing multiple fine pulses for only a subset of the multiple levels of cells being programmed. As used herein, “subset” refers to a proper subset, and thus means that less than all of the levels of cells being programmed receive multiple fine pulses in connection with the partial-fine programming scheme.

More particularly, FIG. 4D shows two example partial-fine program schemes that may be implemented according to some implementations of the disclosure. As shown by reference number 440, a first partial-fine program scheme may include performing a first set of fine pulses for the subset of the multiple levels of cells being programmed prior to performing a second set of fine pulses for each of the multiple levels of cells being programmed. More particularly, the partial fine program scheme indicated by reference number 440 may include first performing a coarse pulse (as indicated by reference number 442) for each level of cells being programmed, which may be substantially similar to the operations described above in connection with reference numbers 428 and 434. Following the coarse pulses, the memory device may apply a fine pulse to a subset (e.g., less than all) of the levels of cells being programmed (e.g., a partial fine pulse, indicated by reference number 444). For example, in the example shown in connection with reference number 440, the memory device may apply a fine pulse to cells being programmed to one of level 10 through level 15, but may refrain from applying a fine pulse to cells being programmed to one of level 1 through level 9. In that regard, following the partial-fine pulse indicated by reference number 444, the threshold voltage distributions for a first subset of levels of cells (e.g., cells being programmed to levels 1 through level 9) may be the same as they were following the coarse pulse (as indicated by using solid lines in both), while the threshold voltage distributions for a second subset of levels of cells (e.g., cells being programmed to levels 10 through level 15) may be narrower than they were following the coarse pulse (as indicated by using solid lines in the coarse pulse and dotted lines in the partial-fine pulse).

Following the partial-fine pulse, a fine pulse (as indicated by reference number 446) may be applied to each of the levels of cells being programmed (e.g., levels 1 through levels 15). In this regard, the partial-fine program scheme may result in a certain subset of cells receiving as many fine pulses as for a double-fine program scheme (e.g., two total, indicated using dashed lines in connection with reference number 446), with a different subset of cells receiving only one fine pulse (e.g., indicated using dotted lines in connection with reference number 446), thereby reducing power consumption and programming time as compared to a double-fine program scheme while still enabling multiple fine pulses for reliability-risk cells (e.g., cells programmed to levels 10 through levels 15 in the example shown in connection with reference number 440). Put another way, following the fine pulse, a first subset of cells (e.g., cells being programmed to level 1 through level 9 in the depicted example) may have received only one fine pulse (as shown using dotted lines), while a second subset of cells (e.g., cells being programmed to level 10 through level 15 in the depicted example) may have received two fine pulses (as shown using dashed lines). In this regard, the second subset of threshold voltage distributions may be tighter as compared to the first subset of threshold voltage distributions, thereby improving a robustness of the second subset of threshold voltage distributions to charge leakage, shifting threshold voltages, and/or other phenomena which may cause read/write errors in the cells associated with second subset of threshold voltage distributions (e.g., level 10 cells through level 15 cells in the example depicted in FIG. 4D). In this regard, the cells that are included in the subset of cells that receive multiple fine pulses in the partial-fine program scheme may be cells that are to be programmed to levels that pose a highest reliability risk. More particularly, in the example shown in FIG. 4D, the uppermost levels of cells (e.g., level 10 cells through level 15 cells) may pose the highest reliability risk in a QLC memory, and thus cells being programmed to level 10 through level 15 may be the cells that are subjected to two fine pulses in the partial-fine program scheme.

Although in the implementation shown in connection with reference number 440 the partial-fine pulse (as indicated by reference number 444) precedes the fine pulse (as indicated by reference number 446), in some other implementations the fine pulse may precede the partial-fine pulse. Put another way, in the example partial-fine program scheme shown in connection with reference number 440, the partial-fine program scheme includes performing a first set of fine pulses for the subset of the multiple levels of cells to receive multiple fine pulses (e.g., level 10 cells through level 15 cells) prior to performing a second set of fine pulses for each of the multiple levels of cells being programmed (e.g., level 1 cells through level 15 cells). However, in some other implementations, a partial-fine program scheme may include performing a first set of fine pulses for each of the multiple levels of cells being programmed prior to performing a second set of fine pulses for the subset of the multiple levels of cells that are to receive multiple fine pulses.

More particularly, as indicated by reference number 448, a second example partial-fine program scheme may include performing a first set of fine pulses for each of the multiple levels of cells being programmed prior to performing a second set of fine pulses for the subset of the multiple levels of cells that are to receive multiple fine pulses (e.g., the second partial-fine program scheme may include performing a fine pulse prior to performing a partial-fine pulse). More particularly, the partial fine program scheme indicated by reference number 448 may include first performing a coarse pulse (as indicated by reference number 450) for each level of cells being programmed, which may be substantially similar to the operations described above in connection with reference numbers 428, 434, and 442. Following the coarse pulses, the memory device may apply a fine pulse (as indicated by reference number 452) to each of the levels of cells being programmed (e.g., cells that are being programmed to level 1 through level 15), resulting in each of the threshold voltage distributions being tightened, as shown using dotted lines. Moreover, following the fine pulse, a subset (e.g., less than all) of the levels of cells being programmed may receive an additional fine pulse, as indicated by reference number 454. For example, in the example shown in connection with reference number 448, the memory device may apply an additional fine pulse to cells being programmed to one of level 10 through level 15 but may refrain from applying an additional fine pulse to cells being programmed to one of level 1 through level 9. In that regard, following the partial-fine pulse indicated by reference number 454, a first subset of threshold voltage distributions (e.g., the threshold voltage distributions associated with level 1 through level 9 in the depicted example) may have received a single fine pulse (as shown using dotted lines), while a second subset of threshold voltage distributions (e.g., the threshold voltage distributions associated with level 10 through level 15 in the depicted example) may have received two fine pulses (as shown using dashed lines).

Although in the implementations shown in FIG. 4D includes cells associated with level 10 through level 15 receiving multiple fine pulses, in some other implementations a different subset of cells may receive multiple fine pulses as part of a partial-fine program scheme. For example, as shown in FIG. 4E, and as indicated by reference number 456, a third example partial-fine program scheme may include performing multiple fine pulses for lower-level cells (e.g., cells being programmed to level 1 through level 6). In such implementations, cells may be programmed using a coarse pulse (as indicated by reference number 458), a partial-fine pulse (as indicated by reference number 460), and a fine pulse (as indicated by reference number 462), which may be substantially similar to the coarse pulses, partial-fine pulses, and fine pulses described above in connection with FIG. 4D. However, in this implementation, cells being programmed to one of level 1 through level 6 may receive two fine pulses (as indicated using dashed lines) while cells being programmed to one level 7 through 15 may have receive only one fine pulse (as indicated using dotted lines).

Additionally, or alternatively, in some implementations a subset of cells that is to receive multiple fine pulses as part of a partial-fine program scheme may be associated with a set of non-contiguous levels. More particularly, as indicated by reference number 464, a fourth example partial-fine program scheme may include performing multiple fine pulses for cells being programmed to one of level 3, level 4, level 6, level 8, level 9, level 10, or level 15 as one example set of non-contiguous levels. In such implementations, cells may be programmed using a coarse pulse (as indicated by reference number 466), a fine pulse (as indicated by reference number 468), and a partial-fine pulse (as indicated by reference number 470), which may be substantially similar to the coarse pulses, partial-fine pulses, and fine pulses described above in connection with FIG. 4D. However, in this implementation, cells being programmed to one of level 3, level 4, level 6, level 8, level 9, level 10, or level 15 may receive two fine pulses (as indicated using dashed lines) while cells being programmed to one of level 1, level 2, level 5, level 7, level 11, level 12, level 13, or level 14 may receive only one fine pulse (as indicated using dotted lines).

FIG. 4F schematically depicts how partial-fine and/or multi-fine programming schemes may be implemented for certain word lines and/or word line zones in a memory. More particularly, reference number 472 shows a multi-deck memory (e.g., a two-deck memory, including two decks shown in FIG. 4F as “Deck 1” and “Deck 2”), with each deck including multiple word lines (shown in FIG. 4F as “WL”). As indicated by reference number 474, in some examples a single-fine program scheme (shown using light stippling) may be implemented for all word lines in a memory. As described above, this may result in relatively low power consumption and/or a relatively short programming time, but may result in reduced reliability as reliability risk word lines may contain read/write errors due to only one fine pulse being used in the programming process. Accordingly, in some implementations, a partial-fine and/or a multi-fine program scheme may be implemented in order to improve a reliability of the memory, such as when a PEC count of the memory satisfies a PEC count threshold, or the like.

More particularly, as indicated by reference number 476, a partial-fine program scheme (indicated using darker stippling) may be used for certain reliability-risk word lines (e.g., word lines that exhibit a poor RWB at high PEC counts). For example, in the implementation indicated by reference number 476, a partial-fine program scheme (e.g., one of the partial-fine program schemes described above in connection with FIGS. 4D-4E or a similar program scheme) may be used for reliability risk word lines, which, in this example, is a group of three word lines included in the lower deck of memory (e.g., Deck 1).

Although in the example indicated by reference number 476 three of sixteen total word lines associated with Deck 1 are included in a word line group that are to be programmed using the partial-fine program scheme, in some other implementations more or less word lines may be included in a word line group that is to be programmed using the partial-fine program scheme. For example, as indicated by reference number 478, in some other implementations four (or more) word lines may be included in a word line group that is to be programmed using the partial-fine program scheme, while, in some other implementations, two or less word lines may be included in a word line group that is to be programmed using the partial-fine program scheme (not shown).

Additionally, or alternatively, in some implementations, a partial-fine program may be used to program word lines that are included in more than one word line zone. For example, as indicated by 480, in some implementations the memory may be associated with multiple word line groups that are to be programmed using the partial-fine program scheme (e.g., multiple reliability risk word line groups). For example, in the implementation depicted by reference number 480, the three lowermost word lines of Deck 1 may form part of a first word line group that is to be programmed using the partial-fine program scheme, and, similarly, the three lowermost word lines of Deck 2 may form part of a second word line group that is to be programmed using the partial-fine program scheme.

Additionally, or alternatively, in some implementations various amounts of fine pulses may be applied to various word lines based on RWB margins, among other examples. For example, as indicated by reference number 482, in some implementations certain word lines may be programmed using a single-fine program scheme, other word lines may be programmed using partial-fine program scheme, and still other word lines may be programmed using a double-fine program scheme (as indicated using striping). Moreover, in some implementations, an upper deck (e.g., Deck 2) and a lower deck (e.g., Deck 1) of a memory may be associated with a different combination of single-fine, partial-fine, double-fine, and/or other multi-fine program schemes. For example, in the implementation indicated by reference number 484, the upper deck (e.g., Deck 2) may include two word lines that are to be programmed using a partial-fine program scheme and one word line that is to be programmed using a double-fine program scheme, with the remaining word lines to be programmed using a single-fine program scheme. On the other hand, the lower deck (e.g., Deck 1) may include three word lines that are to be programmed using another multi-fine program scheme (shown using cross-hatching, which may be, e.g., a triple-fine program scheme), with the remaining word lines to be programmed using a single-fine program scheme.

In some implementations, a partial-fine program scheme used by a memory device to program reliability risk word lines may be associated with a subblock-first program scheme, such as the subblock-first program scheme described above in connection with reference number 316 of FIG. 3B, but in which only a subset of levels of cells being programmed receive a second fine pulse (e.g., in which only a subset of levels of cells being programmed receive both the pulses indicated using “F” and “FF” in the table indicated by reference number 316 in FIG. 3B). However, in some other implementations, a partial-fine program scheme used by a memory device to program reliability risk word lines may be associated with a word-line-first program scheme. For example, FIG. 4G shows a sequence of operations, indicated by reference number 486, that may be used to perform a word-line-first program scheme (e.g., a word-line-first, partial-fine program scheme). In the word-line first program scheme, for a first word line to be programmed (e.g., WL 1), the memory device may perform a coarse pulse on each subblock to be programmed, such as a coarse pulse on subblock 0 (shown as “1C”), a coarse pulse on subblock 1 (shown as “2C”), and so forth through subblock 3 (shown as “4C”). The memory device may then perform a coarse pulse on a first subblock (e.g., subblock 0) of the next WL to be programmed (e.g., WL 2), as shown as “5C.” Rather than proceeding with programming a fine pulse on a first subblock of the first WL (e.g., WL 1), as is the case for a subblock-first program scheme, the memory may, in this implementation, continue with coarse pulses on the word line being programmed (e.g., WL 2) until all coarse pulses have been completed for the given word line. More particularly, after programming the first subblock (e.g., subblock 0) on the second word line (e.g., WL 2), the memory device may perform a coarse pulse on each subblock of the word line to be programmed, such as a coarse pulse on subblock 1 (shown as “6C”), a coarse pulse on subblock 2 (shown as “7C”), and a coarse pulse on subblock 3 (shown as “8C”).

The memory device may then proceed with performing a first fine pulse on a word line for any level of cells that is to receive a first fine pulse (e.g., a subset of levels of cells in implementations in which a partial-fine pulse precedes a fine pulse, as described above in connection with reference number 440, or each level of cells in implementations in which a fine pulse precedes a partial-fine pulse, as described above in connection with reference number 448). For example, the memory device may proceed with programming a fine pulse on subblock 0 of the first word line (shown as “9F”), a fine pulse on subblock 1 of the first word line (shown as “10F”), and so forth through subblock 3 (shown as “12F”). Similarly, the memory device may then proceed with performing a second fine pulse on a word line for any level of cells that is to receive a second fine pulse (e.g., each level of cell in implementations in which a partial-fine pulse precedes a fine pulse, as described above in connection with reference number 440, or a subset of levels of cells in implementations in which a fine pulse precedes a partial-fine pulse, as described above in connection with reference number 448). For example, the memory device may proceed with programming a second fine pulse on subblock 0 of the first word line (shown as “13FF”), a second fine pulse on subblock 1 of the first word line (shown as “14FF”), and so forth through subblock 3 (shown as “16FF”).

More generally, for the second and subsequent word lines, for a given word line M, the first subblock (e.g., subblock 0) may be associated with an N-th coarse pulse, an (N+16)-th fine pulse, and an (N+20)-th second fine pulse; the second subblock (e.g., subblock 1) may be associated with an (N+1)-th coarse pulse, an (N+17)-th fine pulse, and an (N+21)-th second fine pulse; the third subblock (e.g., subblock 2) may be associated with an (N+2)-th coarse pulse, an (N+18)-th fine pulse, and an (N+22)-th second fine pulse; and the fourth subblock (e.g., subblock 3) may be associated with an (N+3)-th coarse pulse, an (N+19)-th fine pulse, and an (N+23)-th second fine pulse. In this way, the memory device may be configured to complete a certain type of pulse (e.g., a coarse pulse, a fine pulse, a second fine pulse, or the like) for a given word line before moving onto another word line and/or type of pulse.

As indicated above, FIGS. 4A-4G are provided as examples. Other examples may differ from what is described with regard to FIGS. 4A-4G.

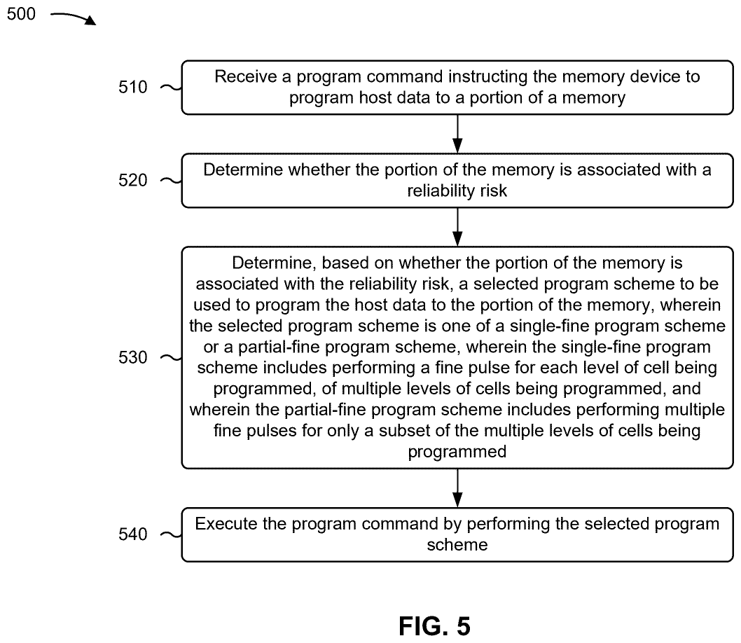

FIG. 5 is a flowchart of an example method 500 associated with a partial-fine program scheme for reliability risk word lines. In some implementations, a memory device (e.g., memory device 120) may perform or may be configured to perform the method 500. In some implementations, another device or a group of devices separate from or including the memory device (e.g., memory system 110) may perform or may be configured to perform the method 500. Additionally, or alternatively, one or more components of a memory system (e.g., memory system controller 115, local controller 125, memory array 130) may perform or may be configured to perform the method 500. Thus, means for performing the method 500 may include the memory device and/or one or more components of the memory device and/or one or more components of a memory system (e.g., memory system 110). Additionally, or alternatively, a non-transitory computer-readable medium may store one or more instructions that, when executed by the memory device (e.g., the local controller 125 of the memory device 120), cause the memory device to perform the method 500.

As shown in FIG. 5, the method 500 may include receiving a program command instructing the memory device to program host data to a portion of a memory (block 510). As further shown in FIG. 5, the method 500 may include determining whether the portion of the memory is associated with a reliability risk (block 520). As further shown in FIG. 5, the method 500 may include determining, based on whether the portion of the memory is associated with the reliability risk, a selected program scheme to be used to program the host data to the portion of the memory, wherein the selected program scheme is one of a single-fine program scheme or a partial-fine program scheme, wherein the single-fine program scheme includes performing a fine pulse for each level of cells being programmed, of multiple levels of cells being programmed, and wherein the partial-fine program scheme includes performing multiple fine pulses for only a subset of the multiple levels of cells being programmed (block 530). As further shown in FIG. 5, the method 500 may include executing the program command by performing the selected program scheme (block 540).

The method 500 may include additional aspects, such as any single aspect or any combination of aspects described below and/or described in connection with one or more other methods or operations described elsewhere herein.

In a first aspect, determining whether the portion of the memory is associated with the reliability risk comprises determining a PEC count associated with the portion of the memory, and determining, based on the PEC count, whether the portion of the memory is associated with the reliability risk.

In a second aspect, alone or in combination with the first aspect, determining the selected program scheme to be used to program the host data to the portion of the memory comprises selecting the single-fine program scheme based on the portion of the memory not being associated with the reliability risk, and selecting the partial-fine program scheme based on the portion of the memory being associated with the reliability risk.

In a third aspect, alone or in combination with one or more of the first and second aspects, the portion of the memory is associated with a word line, the word line is associated with a word line group, and determining whether the portion of the memory is associated with the reliability risk comprises determining whether the word line group is associated with the reliability risk.

In a fourth aspect, alone or in combination with one or more of the first through third aspects, determining whether the portion of the memory is associated with the reliability risk comprises determining whether the portion of the memory is associated with a first reliability risk category, a second reliability risk category, or a third reliability risk category, and wherein determining the selected program scheme to be used to program the host data to the portion of the memory includes selecting the single-fine program scheme based on the portion of the memory being associated with the first reliability risk category, selecting the partial-fine program scheme based on the portion of the memory being associated with the second reliability risk category, or selecting a multi-fine program scheme based on the portion of the memory being associated with the third reliability risk category, wherein the multi-fine program scheme includes performing multiple fine pulses for each of the multiple levels of cells being programmed.

In a fifth aspect, alone or in combination with one or more of the first through fourth aspects, the method 500 includes performing, by the memory device, a first set of fine pulses for the subset of the multiple levels of cells being programmed prior to performing a second set of fine pulses for each of the multiple levels of cells being programmed.

In a sixth aspect, alone or in combination with one or more of the first through fifth aspects, the method 500 includes performing, by the memory device, a first set of fine pulses for each of the multiple levels of cells being programmed prior to performing a second set of fine pulses for the subset of the multiple levels of cells being programmed.

In a seventh aspect, alone or in combination with one or more of the first through sixth aspects, determining whether the portion of the memory is associated with the reliability risk includes determine whether the portion of the memory is associated with the reliability risk using a lookup table.

In an eighth aspect, alone or in combination with one or more of the first through seventh aspects, the partial-fine program scheme is associated with a word-line-first program scheme.

In a ninth aspect, alone or in combination with one or more of the first through eighth aspects, the partial-fine program scheme is associated with a subblock-first program scheme.

Although FIG. 5 shows example blocks of a method 500, in some implementations, the method 500 may include additional blocks, fewer blocks, different blocks, or differently arranged blocks than those depicted in FIG. 5. Additionally, or alternatively, two or more of the blocks of the method 500 may be performed in parallel. The method 500 is an example of one method that may be performed by one or more devices described herein. These one or more devices may perform or may be configured to perform one or more other methods based on operations described herein.

In some implementations, a memory device includes one or more components configured to: receive, from a host device, a program command instructing the memory device to program host data to a portion of a memory; determine whether the portion of the memory is associated with a reliability risk; determine, based on whether the portion of the memory is associated with the reliability risk, a selected program scheme to be used to program the host data to the portion of the memory, wherein the selected program scheme is one of a single-fine program scheme or a partial-fine program scheme, wherein the single-fine program scheme includes performing a fine pulse for each level of cells being programmed, of multiple levels of cells being programmed, and wherein the partial-fine program scheme includes performing multiple fine pulses for only a subset of the multiple levels of cells being programmed; and execute the program command by performing the selected program scheme.

In some implementations, a method includes receiving, by a memory device from a host device, a program command instructing the memory device to program host data to a portion of a memory; determining, by the memory device, whether the portion of the memory is associated with a reliability risk; determining, by the memory device and based on whether the portion of the memory is associated with the reliability risk, a selected program scheme to be used to program the host data to the portion of the memory, wherein the selected program scheme is one of a single-fine program scheme or a partial-fine program scheme, wherein the single-fine program scheme includes performing a fine pulse for each level of cells being programmed, of multiple levels of cells being programmed, and wherein the partial-fine program scheme includes performing multiple fine pulses for only a subset of the multiple levels of cells being programmed; and executing, by the memory device, the program command by performing the selected program scheme.

In some implementations, a non-transitory computer-readable medium storing a set of instructions includes one or more instructions that, when executed by one or more processors of a memory device, cause the memory device to: receive a program command instructing the memory device to program host data to a portion of a memory; determine whether the portion of the memory is associated with a reliability risk; determine, based on whether the portion of the memory is associated with the reliability risk, a selected program scheme to be used to program the host data to the portion of the memory, wherein the selected program scheme is one of a single-fine program scheme or a partial-fine program scheme, wherein the single-fine program scheme includes performing a fine pulse for each level of cells being programmed, of multiple levels of cells being programmed, and wherein the partial-fine program scheme includes performing multiple fine pulses for only a subset of the multiple levels of cells being programmed; and execute the program command by performing the selected program scheme.

The foregoing disclosure provides illustration and description but is not intended to be exhaustive or to limit the implementations to the precise forms disclosed. Modifications and variations may be made in light of the above disclosure or may be acquired from practice of the implementations described herein.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory device, comprising:
one or more components configured to:
receive, from a host device, a program command instructing the memory device to program host data to a portion of a memory;
determine whether the portion of the memory is associated with a reliability risk;
determine, based on whether the portion of the memory is associated with the reliability risk, a selected program scheme to be used to program the host data to the portion of the memory, wherein the selected program scheme is one of a single-fine program scheme or a partial-fine program scheme,
wherein the single-fine program scheme includes performing a fine pulse for each level of cells being programmed, of multiple levels of cells being programmed, and
wherein the partial-fine program scheme includes performing multiple fine pulses for only a subset of the multiple levels of cells being programmed; and
execute the program command by performing the selected program scheme.

2. The memory device of claim 1, wherein the one or more components, to determine whether the portion of the memory is associated with the reliability risk, are configured to:
determine a program erase cycle (PEC) count associated with the portion of the memory; and
determine, based on the PEC count, whether the portion of the memory is associated with the reliability risk.

3. The memory device of claim 1, wherein the one or more components, to determine the selected program scheme to be used to program the host data to the portion of the memory, are configured to:
select the single-fine program scheme based on the portion of the memory not being associated with the reliability risk; and
select the partial-fine program scheme based on the portion of the memory being associated with the reliability risk.

4. The memory device of claim 1, wherein the portion of the memory is associated with a word line,
wherein the word line is associated with a word line group, and
wherein the one or more components, to determine whether the portion of the memory is associated with the reliability risk, are configured to determine whether the word line group is associated with the reliability risk.

5. The memory device of claim 1, wherein the one or more components, to determine whether the portion of the memory is associated with the reliability risk, are configured to determine whether the portion of the memory is associated with the reliability risk using a lookup table.

6. The memory device of claim 1, wherein the one or more components, to determine whether the portion of the memory is associated with the reliability risk, are configured to determine whether the portion of the memory is associated with a first reliability risk category, a second reliability risk category, or a third reliability risk category, and
wherein one or more components, to determine the selected program scheme to be used to program the host data to the portion of the memory, are configured to:
select the single-fine program scheme based on the portion of the memory being associated with the first reliability risk category;
select the partial-fine program scheme based on the portion of the memory being associated with the second reliability risk category; or
select a multi-fine program scheme based on the portion of the memory being associated with the third reliability risk category, wherein the multi-fine program scheme includes performing multiple fine pulses for each of the multiple levels of cells being programmed.

7. The memory device of claim 1, wherein the partial-fine program scheme is associated with a word-line-first program scheme.

8. The memory device of claim 1, wherein the partial-fine program scheme is associated with a subblock-first program scheme.

9. The memory device of claim 1, wherein the partial-fine program scheme includes performing a first set of fine pulses for the subset of the multiple levels of cells being programmed prior to performing a second set of fine pulses for each of the multiple levels of cells being programmed.

10. The memory device of claim 1, wherein the partial-fine program scheme includes performing a first set of fine pulses for each of the multiple levels of cells being programmed prior to performing a second set of fine pulses for the subset of the multiple levels of cells being programmed.

11. A method, comprising:
receiving, by a memory device from a host device, a program command instructing the memory device to program host data to a portion of a memory;
determining, by the memory device, whether the portion of the memory is associated with a reliability risk;
determining, by the memory device and based on whether the portion of the memory is associated with the reliability risk, a selected program scheme to be used to program the host data to the portion of the memory, wherein the selected program scheme is one of a single-fine program scheme or a partial-fine program scheme,
wherein the single-fine program scheme includes performing a fine pulse for each level of cells being programmed, of multiple levels of cells being programmed, and
wherein the partial-fine program scheme includes performing multiple fine pulses for only a subset of the multiple levels of cells being programmed; and
executing, by the memory device, the program command by performing the selected program scheme.

12. The method of claim 11, wherein determining whether the portion of the memory is associated with the reliability risk comprises:
determining, by the memory device, a program erase cycle (PEC) count associated with the portion of the memory; and
determining, by the memory device and based on the PEC count, whether the portion of the memory is associated with the reliability risk.

13. The method of claim 11, wherein determining the selected program scheme to be used to program the host data to the portion of the memory comprises:
selecting, by the memory device, the single-fine program scheme based on the portion of the memory not being associated with the reliability risk; and
selecting, by the memory device, the partial-fine program scheme based on the portion of the memory being associated with the reliability risk.

14. The method of claim 11, wherein the portion of the memory is associated with a word line,
wherein the word line is associated with a word line group, and
wherein determining whether the portion of the memory is associated with the reliability risk comprises determining whether the word line group is associated with the reliability risk.

15. The method of claim 11, wherein determining whether the portion of the memory is associated with the reliability risk comprises determining whether the portion of the memory is associated with a first reliability risk category, a second reliability risk category, or a third reliability risk category, and
wherein determining the selected program scheme to be used to program the host data to the portion of the memory includes:
selecting, by the memory device, the single-fine program scheme based on the portion of the memory being associated with the first reliability risk category;
selecting, by the memory device, the partial-fine program scheme based on the portion of the memory being associated with the second reliability risk category; or
selecting, by the memory device, a multi-fine program scheme based on the portion of the memory being associated with the third reliability risk category, wherein the multi-fine program scheme includes performing multiple fine pulses for each of the multiple levels of cells being programmed.

16. The method of claim 11, further comprising performing, by the memory device, a first set of fine pulses for the subset of the multiple levels of cells being programmed prior to performing a second set of fine pulses for each of the multiple levels of cells being programmed.

17. The method of claim 11, further comprising performing, by the memory device, a first set of fine pulses for each of the multiple levels of cells being programmed prior to performing a second set of fine pulses for the subset of the multiple levels of cells being programmed.

18. A non-transitory computer-readable medium storing a set of instructions, the set of instructions comprising:
one or more instructions that, when executed by one or more processors of a memory device, cause the memory device to:
receive a program command instructing the memory device to program host data to a portion of a memory;
determine whether the portion of the memory is associated with a reliability risk;
determine, based on whether the portion of the memory is associated with the reliability risk, a selected program scheme to be used to program the host data to the portion of the memory, wherein the selected program scheme is one of a single-fine program scheme or a partial-fine program scheme,
wherein the single-fine program scheme includes performing a fine pulse for each level of cells being programmed, of multiple levels of cells being programmed, and
wherein the partial-fine program scheme includes performing multiple fine pulses for only a subset of the multiple levels of cells being programmed; and
execute the program command by performing the selected program scheme.

19. The non-transitory computer-readable medium of claim 18, wherein the partial-fine program scheme includes performing a first set of fine pulses for the subset of the multiple levels of cells being programmed prior to performing a second set of fine pulses for each of the multiple levels of cells being programmed.

20. The non-transitory computer-readable medium of claim 18, wherein the partial-fine program scheme includes performing a first set of fine pulses for each of the multiple levels of cells being programmed prior to performing a second set of fine pulses for the subset of the multiple levels of cells being programmed.
